(19) United States
(12) Patent Application Publication
(10) Pub. No.: US 2008/0173471 A1
(43) Pub. Date: Jul. 24, 2008

(54) Element substrate and method of manufacturing the same

(75) Inventors: Toshihiko Kaneda, Hakusan (JP); Satoshi Kimura, Fujimi (JP); Hidemichi Furihata, Chino (JP); Jun Amako, Matsumoto (JP); Daisuke Sawaki, Shiojiri (JP); Takeshi Kijima, Matsumoto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 12/009,161

(22) Filed: Jan. 16, 2008

(30) Foreign Application Priority Data
Jan. 22, 2007 (JP) 2007-11652
Jan. 22, 2007 (JP) 2007-11653

(51) Int. Cl. H05K 1/09; H05K 3/02

(52) U.S. Cl. 174/257; 29/847

(57) ABSTRACT

An element substrate including a substrate and a metal layer formed on the substrate by electroless plating and including a linear portion having a width of 10 nm to 100 nm.

Japanese Patent Application No. 2007-11652, filed on Jan. 22, 2007, and Japanese Patent Application No. 2007-11653, filed on Jan. 22, 2007, are hereby incorporated by reference in their entirety.

### BACKGROUND OF THE INVENTION

The present invention relates to an element substrate and a method of manufacturing the same.

For example, metal wires and the like are formed on a substrate using a subtractive method. In the subtractive method, a metal layer is formed over the entire surface of a substrate, and a photoresist is applied to the metal layer and patterned. The metal layer is then etched using the photoresist as a mask. This method requires a vacuum device. Moreover, since the pattern accuracy of the metal layer varies depending on the pattern accuracy of the photoresist, it is difficult to accurately form a minute pattern at a nanometer level.

### SUMMARY

According to a first aspect of the invention, there is provided a method of manufacturing an element substrate comprising:

(a) forming a sacrificial layer with a first pattern on a substrate;

(b) forming a metal layer over a formation region and a non-formation region of the sacrificial layer; and

(c) removing the sacrificial layer by heating to give a second pattern to the metal layer.

According to a second aspect of the invention, there is provided an element substrate comprising:

a substrate; and

a metal layer formed on the substrate by electroless plating and including a linear portion having a width of 10 nm to 100 nm.

### BRIEF DESCRIPTION OF THE SEVERAL VIEWS OF THE DRAWING

FIG. 1 is a diagram showing the method of manufacturing an element substrate according to one embodiment of the invention.

FIG. 2 is a diagram showing the method of manufacturing an element substrate according to one embodiment of the invention.

FIG. 3 is a diagram showing the method of manufacturing an element substrate according to one embodiment of the invention.

FIG. 4 is a diagram showing the method of manufacturing an element substrate according to one embodiment of the invention.

FIG. 5 is a diagram showing the method of manufacturing an element substrate according to one embodiment of the invention.

FIG. 6 is a diagram showing the method of manufacturing an element substrate according to one embodiment of the invention.

FIG. 7 is a diagram showing the method of manufacturing an element substrate according to one embodiment of the invention.

FIG. 8 is a diagram showing the method of manufacturing an element substrate according to one embodiment of the invention.

FIG. 9 is a diagram showing the method of manufacturing an element substrate according to one embodiment of the invention.

FIG. 10 is a diagram showing the method of manufacturing an element substrate according to one embodiment of the invention.

FIG. 11 is a diagram showing the method of manufacturing an element substrate according to one embodiment of the invention.

FIG. 12 is a diagram showing the method of manufacturing an element substrate according to one embodiment of the invention.

FIG. 13 is a diagram showing the method of manufacturing an element substrate according to one embodiment of the invention.

FIG. 14 is a diagram showing the method of manufacturing an element substrate according to one embodiment of the invention.

FIG. 15 is a cross-sectional view schematically showing an element substrate according to one embodiment of the invention.

FIG. 16 shows an example of an electronic device to which an element substrate according to one embodiment of the invention is applied.

FIG. 17 shows an SEM image showing a method of manufacturing an element substrate according to Experimental Example 1.

FIG. 18 shows an SEM image showing an element substrate according to Experimental Example 1.

FIG. 19 shows an SEM image showing an element substrate according to Experimental Example 1.

FIG. 20 shows an SEM image showing an element substrate according to Experimental Example 1.

FIG. 21 shows an SEM image showing an element substrate according to Experimental Example 1.

FIG. 22 shows an SEM image showing an element substrate according to Experimental Example 1.

FIG. 23 shows an SEM image showing a method of manufacturing an element substrate according to Experimental Example 2.

FIG. 24 shows an SEM image showing an element substrate according to Experimental Example 2.

FIG. 25 shows an SEM image showing an element substrate according to Experimental Example 2.

### DETAILED DESCRIPTION OF THE EMBODIMENT

The invention may provide an element substrate in which a metal layer with a minute pattern is formed with high accuracy, and a method of manufacturing the same.

According to one embodiment of the invention, there is provided a method of manufacturing an element substrate comprising:

(a) forming a sacrificial layer with a first pattern on a substrate;

(b) forming a metal layer over a formation region and a non-formation region of the sacrificial layer; and

(c) removing the sacrificial layer by heating to give a second pattern to the metal layer.

In the method of manufacturing an element substrate of this embodiment, a region of the first pattern may be within a region of the second pattern.

In the method of manufacturing an element substrate of this embodiment, a region of the second pattern may be within a region of the first pattern.

In the step (c) of the method of manufacturing an element substrate of this embodiment, the metal layer may be moved by heating to have the second pattern.

In the step (c) of the method of manufacturing an element substrate of this embodiment, the metal layer may be moved to the formation region of the removed sacrificial layer by heating.

In the step (b) of the method of manufacturing an element substrate of this embodiment, the metal layer may be formed by electroless plating.

In the method of manufacturing an element substrate of this embodiment, the step (b) may include:

immersing the substrate in a catalyst adsorption solution containing a surfactant or a silane coupling agent to form a catalyst adsorption layer;

immersing the substrate having the catalyst adsorption layer in a catalyst solution to form a catalyst layer on the catalyst adsorption layer; and immersing the substrate having the catalyst layer in an electroless plating solution to deposit the metal layer on the catalyst layer.

In the step (c) of the method of manufacturing an element substrate of this embodiment, the sacrificial layer may be gasified and removed by heating.

In the method of manufacturing an element substrate of this embodiment, the sacrificial layer may include a resin.

In the method of manufacturing an element substrate of this embodiment, the step (a) may include:

applying a resin material in a fluid state to the substrate;

transferring the first pattern to the resin material by pressing a nanostamper having a depressed pattern of the first pattern against the substrate; and

curing the resin material having the transferred first pattern.

The method of manufacturing an element substrate of this embodiment may further comprise, between the steps (a) and (b), removing an upper portion of the cured resin material and another part of the cured resin material in a region other than the first pattern by ashing.

In the method of manufacturing an element substrate of this embodiment,

the sacrificial layer may include a photoresist; and

the sacrificial layer may be formed by an interference exposure method in the step (a).

According to one embodiment of the invention, there is provided an element substrate comprising:

a substrate; and

a metal layer formed on the substrate by electroless plating and including a linear portion having a width of 10 nm to 100 nm.

In the element substrate of this embodiment, the metal layer may include a plurality of the linear portions having the same width and being parallel to each other on the substrate.

In the element substrate of this embodiment, the linear portion may have a width of 10 nm to 80 nm.

In the element substrate of this embodiment, the linear portions may have an interval of 70 nm to 140 nm in a direction of the width.

In the element substrate of this embodiment, the metal layer may include platinum.

In the element substrate of this embodiment, the width of each of the linear portions may be smaller than an interval between the linear portions in a direction of the width.

In the element substrate of this embodiment, the metal layer may have an aspect ratio of 1 to 3.

Some embodiments of the invention will be described below, with reference to the drawings.

### 1. METHOD OF MANUFACTURING ELEMENT SUBSTRATE

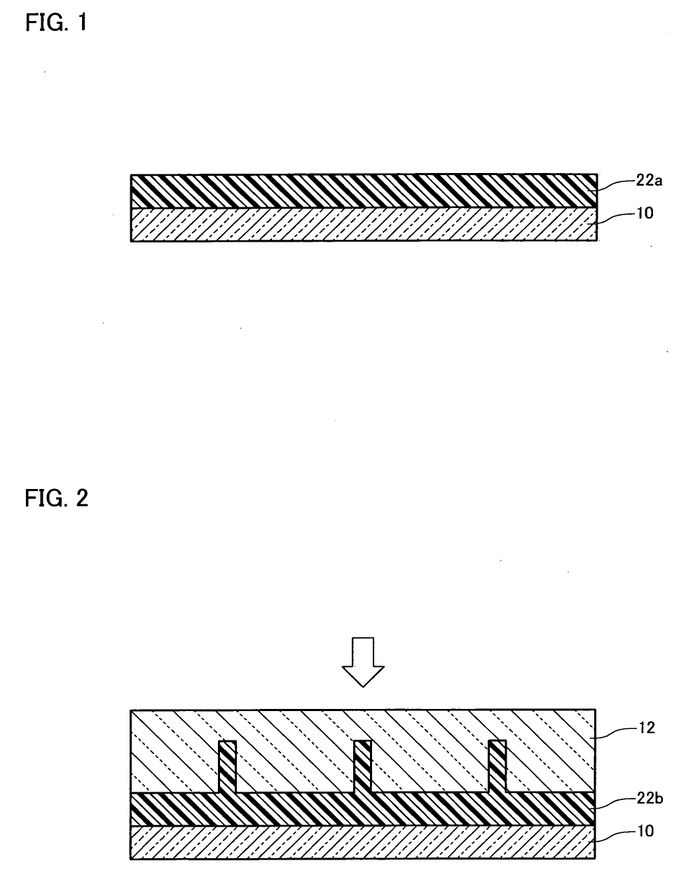

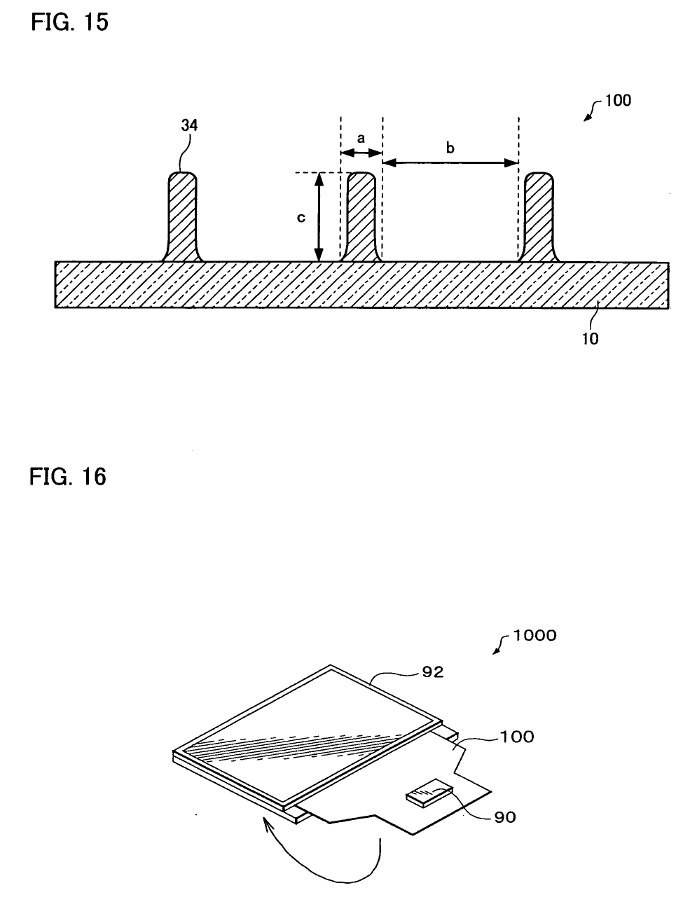

FIGS. 1 to 14 are diagrams showing a method of manufacturing an element substrate (see FIG. 15). In this embodiment, the element substrate is manufactured by applying electroless plating.

(1) A substrate 10 is provided. The substrate 10 may be an insulating substrate, as shown in FIG. 2. A wiring board may be manufactured by forming a metal layer on an insulating substrate by steps described later. The substrate 10 may be an optically-transparent substrate (e.g. transparent substrate) which transmits visible light. An optical element substrate such as a polarizer may be manufactured by forming a metal layer on an optically-transparent substrate by steps described later.

The substrate 10 may be an inorganic substrate (e.g., quartz glass, silicon wafer, or oxide layer). The substrate 10 includes a single-layer substrate and a multilayer substrate in which at least one insulating layer is formed on a base substrate. In this embodiment, a metal layer is formed on the substrate 10. The substrate 10 preferably has a flat surface. It is desirable that the height of unevenness on the surface of the substrate 10 be less than 10 nm, for example.

(2) A sacrificial layer 22 with a first pattern is formed on the substrate 10. The material for the sacrificial layer 22 is not particularly limited insofar as the material can be easily molded and can be removed by a heat treatment. As examples of a material which satisfies such a requirement, resins such as a photoresist, a thermoplastic resin, or a photocurable resin can be given. A resin which is gasified at 300° C. to 400° C. is preferable. Specifically, polymethyl methacrylate (PMMA), polycarbonate, or polystyrene may be used as the material for the sacrificial layer 22. The sacrificial layer 22 may be formed using a known method such as an interference exposure method or nanoimprint technology. This embodiment illustrates the case of forming the sacrificial layer 22 using the nanoimprint technology.

As shown in FIG. 1, a resin material 22a in a fluid state is applied to the substrate 10. A thermoplastic resin, a photocurable resin, or the like may be used as the resin material 22a. As the application method, a known method such as spin coating or dip coating may be used.

A nanostamper 12 is then pressed against the resin material in the direction toward the substrate 10 (arrow direction in FIG. 2) to transfer the first pattern to the resin material. The shape of the first pattern is not particularly limited. The first pattern may be a periodic pattern in which lines are arranged at specific intervals, for example. When the resin material 22a is a photocurable resin, an optically-transparent nanostamper 12 may be used.

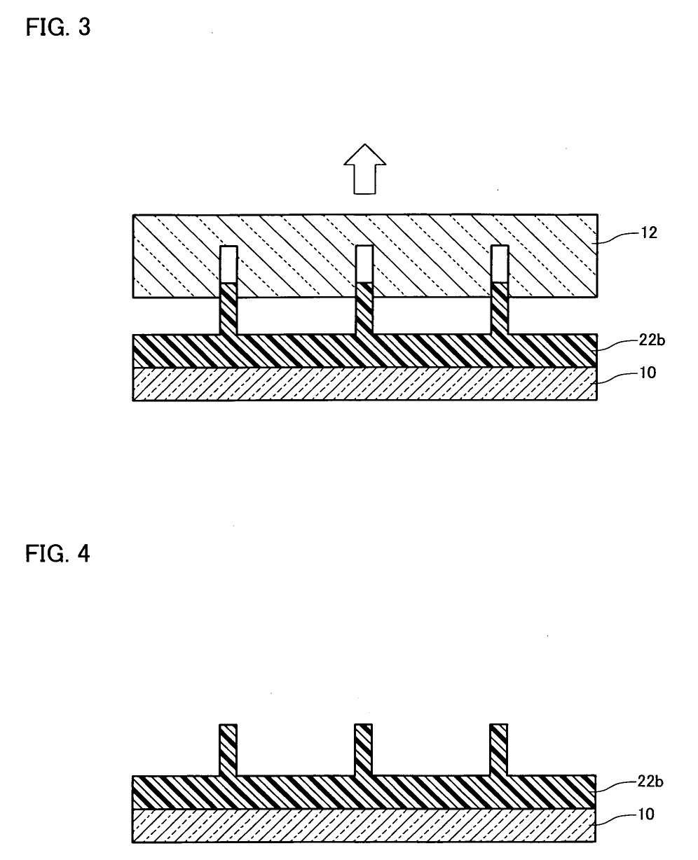

The resin material 22a is then cured to form a sacrificial layer 22b. The nanostamper 12 is then removed from the sacrificial layer 22b (see FIG. 3). The sacrificial layer 22b having the first pattern can be thus formed, as shown in FIG. 4.

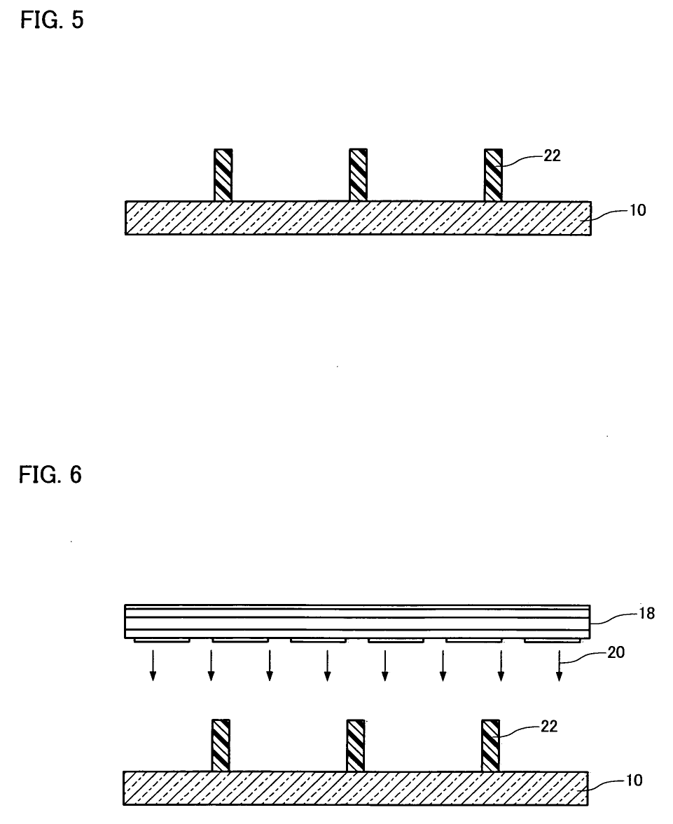

A step (3) described later may be performed using the sacrificial layer 22b, or the sacrificial layer 22b may be partially removed by etching back or the like in the region other than the first pattern, as shown in FIG. 5. When the sacrificial layer 22b is formed of a photoresist, the sacrificial layer 22b may be partially removed by ashing. In this case, the upper portion of the sacrificial layer 22b formed in the region of the first pattern is also removed together with part of the sacrificial layer 22b formed in the region other than the first pattern. The sacrificial layer 22 can be formed by performing this removal step.

The sacrificial layer 22 is formed using the nanoimprint technology in this manner. The sacrificial layer 22 may also formed using the interference exposure method, as described above. When using the interference exposure method, it is preferable to use a photoresist as the resin material 22a and provide an antireflective film on the substrate 10 in advance.

(3) The surfaces of the substrate 10 and the sacrificial layer 22 are then washed. The surfaces of the substrate 10 and the sacrificial layer 22 may be dry-washed or wet-washed. It is preferable to dry-wash the surfaces of the substrate 10 and the sacrificial layer 22. Dry washing prevents the sacrificial layer 22 from being damaged (e.g., separation).

As shown in FIG. 6, dry washing may be performed by applying vacuum ultraviolet rays 20 for 30 to 900 seconds in a nitrogen atmosphere using a vacuum ultraviolet lamp 18 (wavelength: 172 nm, output: 10 mW, distance from the sample: 1 mm). Soil such as oils and fats adhering to the surface of the substrate 10 can be removed by washing the substrate 10.

The substrate 10 and the sacrificial layer 22 may be wet-washed by immersing the substrate 10 and the sacrificial layer 22 in ozone water (ozone concentration: 10 to 20 ppm) at room temperature for about 5 to 30 minutes, for example.

(4) A catalyst adsorption layer 24 containing a surfactant or a silane coupling agent is formed on the substrate 10.

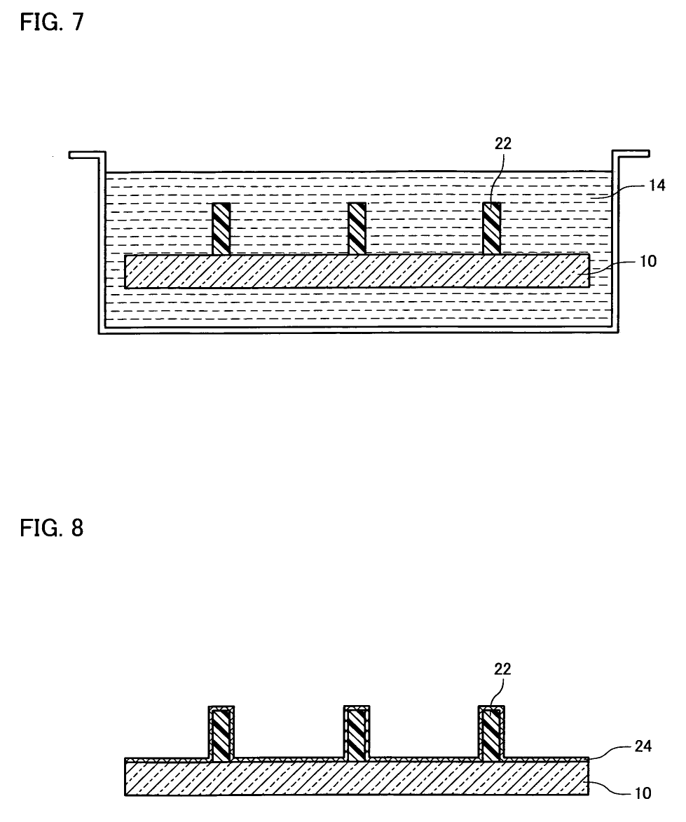

As shown in FIG. 7, the substrate 10 is immersed in a catalyst adsorption solution 14 in which a surfactant or a silane coupling agent is dissolved. When the surface potential in liquid of the substrate 10 is negative, it is preferable to use a cationic surfactant. This is because the cationic surfactant is easily adsorbed on the substrate 10 in comparison with other surfactants.

As the cationic surfactant, a water-soluble surfactant containing an aminosilane component, an alkylammonium surfactant (e.g., cetyltrimethylammonium chloride, cetyltrimethylammonium bromide, or cetyldimethylammonium bromide), or the like may be used.

As the silane coupling agent contained in the catalyst adsorption solution 14, hexamethyldisilazane or the like may be used. The immersion time may be about 1 to 10 minutes, for example.

The substrate 10 is then removed from the catalyst adsorption solution 14 and washed with ultrapure water. After air-drying the substrate 10 at room temperature or removing waterdrops from the substrate 10 by spraying compressed air, the substrate 10 is dried in an oven at 90° C. to 120° C. for about 10 minutes to 1 hour. The catalyst adsorption layer 24 can be formed on the substrate 10 by the above steps, as shown in FIG. 8. When using the cationic surfactant as the surfactant, the surface potential in liquid of the substrate 10 is shifted to the positive potential side in comparison with the surface potential before adsorption.

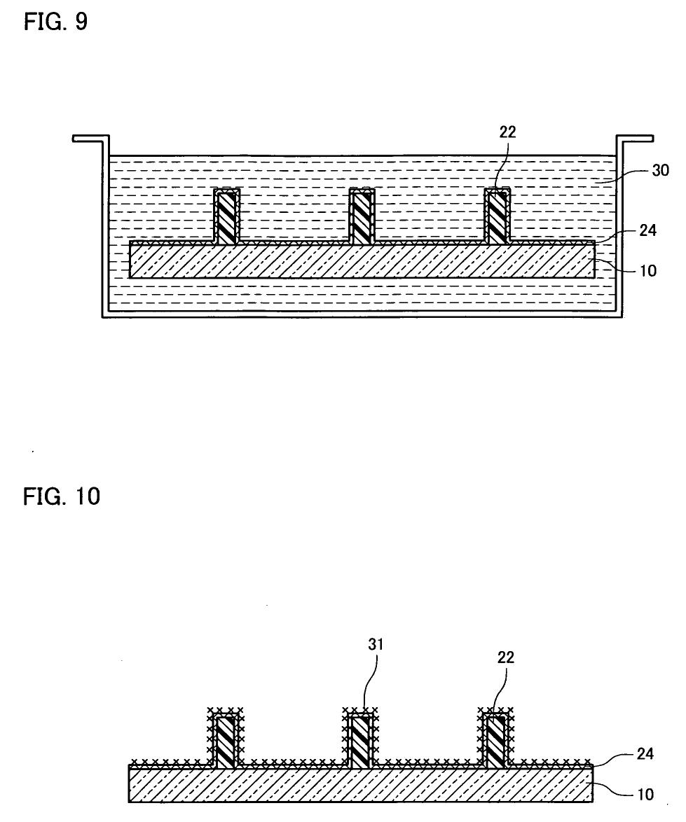

(5) A catalyst layer 31 is formed on the catalyst adsorption layer 24. As shown in FIG. 9, the substrate 10 is immersed in a catalyst solution 30. The catalyst solution 30 contains a catalyst component which functions as an electroless plating catalyst. As the catalyst component, palladium or the like may be used.

The catalyst solution 30 may be prepared as follows, for example.

(5a) Palladium pellets with a purity of 99.99% are dissolved in a mixed solution of hydrochloric acid, a hydrogen peroxide solution, and water to prepare a palladium chloride solution with a palladium concentration of 0.1 to 0.5 g/l.

(5b) The palladium concentration of the palladium chloride solution is adjusted to 0.01 to 0.05 μl by diluting the palladium chloride solution with water and a hydrogen peroxide solution.

(5c) The pH of the palladium chloride solution is adjusted to 4.5 to 6.8 using a sodium hydroxide aqueous solution or the like.

The substrate 10 may be washed with water after immersion in the catalyst solution 30. The substrate 10 may be washed with pure water. A catalyst residue can be prevented from being mixed into an electroless plating solution described later by washing the substrate 10 with water.

The catalyst layer 31 is formed by the above steps. As shown in FIG. 10, the catalyst layer 31 is formed on the top surface of the catalyst adsorption layer 24 on the substrate 10 and the sacrificial layer 22.

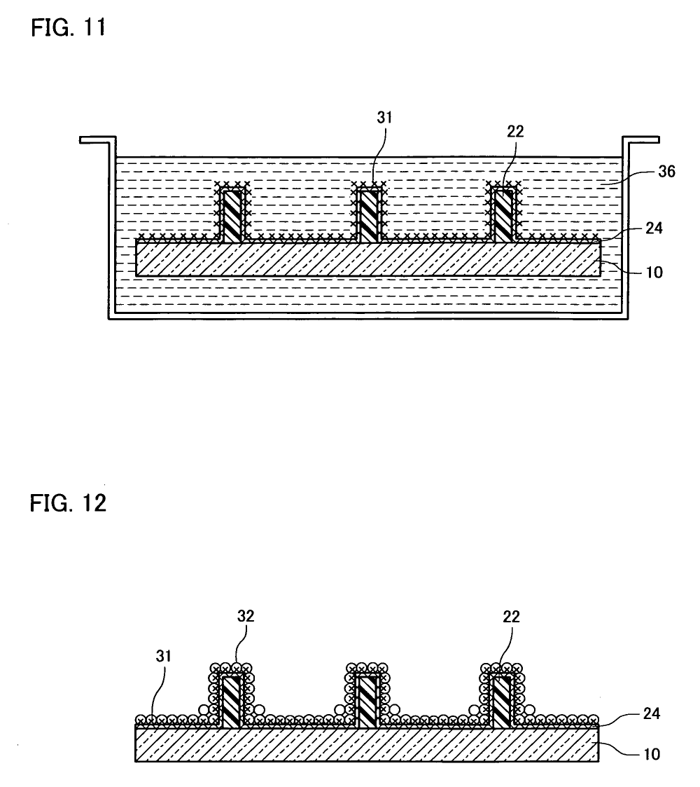

(6) A metal layer 32 is deposited on the substrate 10 (see FIG. 12). The metal layer 32 is formed in the region in which the catalyst layer 31 is formed. As shown in FIG. 11, the metal layer 33 may be deposited by immersing the substrate 10 in a metal-containing electroless plating solution 36.

The electroless plating solution 36 is preferably prepared so that plating particles deposited on the substrate 10 have an average particle diameter of 20 nm or less, and more preferably about 4 to 6 nm. Metal particles forming the metal layer 32 can easily move in a heat treatment step (7) described later by adjusting the size of the plating particles to 4 to 6 nm. Such an electroless plating solution 36 may be prepared by changing the pH, temperature, preparation time, and the like. If the substrate 10 is immersed in the electroless plating solution 36 for a period of time equal to or longer than a specific time, the average particle diameter of the plating particles becomes greater than 20 nm. Therefore, it is preferable that the immersion time be equal to or less than the specific time.

The metal may be platinum, for example. The electroless plating solution 36 is classified as an electroless plating solution used in an acidic region and an electroless plating solution used in an alkaline region. As an example of the electroless plating solution 36, a solution used in an alkaline region is applied. The electroless plating solution 36 contains the above-mentioned metal, a reducing agent, a complexing agent, and the like. Specifically, a mixed solution prepared by mixing a commercially-available platinum plating solution and a reducing agent solution and adjusting the pH of the resulting mixture to 9.5 to 10.5 using sulfuric acid may be used as the electroless plating solution 36. A platinum layer with a thickness of 10 to 40 nm may be formed by immersing the substrate 10 in the above mixed solution (temperature: 40° C. to 50° C.) for about 5 to 15 minutes. The particle diameter of the platinum layer deposited is preferably about 4 to 6 nm.

The metal is not limited to platinum. Nickel, copper, or the like may be used. The particulate metal layer 32 can be formed in this manner. The substrate 10 may be washed with water after forming the metal layer 32. The substrate 10 may be washed with pure water, steam, or pure water and steam.

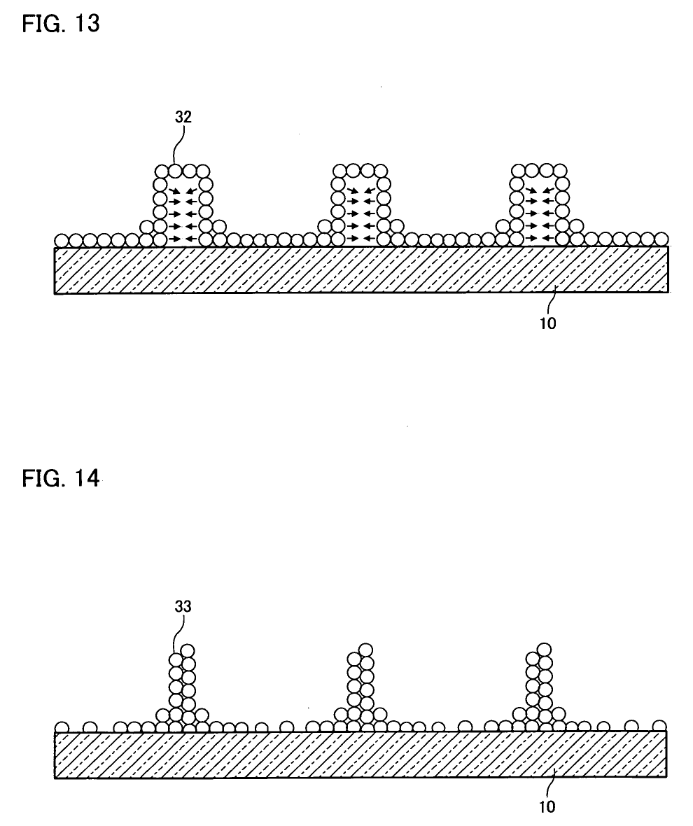

(7) The sacrificial layer 22 is removed by heating the substrate 10 to form a metal layer 34 with a second pattern (see FIG. 15). The substrate 10 is preferably heated in air at 300° C. to 700° C. for about 5 to 30 minutes by rapid thermal annealing (RTA), for example. As shown in FIG. 13, the sacrificial layer 22 is removed by this heat treatment step. The metal particles forming the metal layer 32 aggregate so that the formation region of the sacrificial layer 22 is filled therewith while the sacrificial layer 22 is removed, whereby a metal layer 33 with a shape shown in FIG. 14 is formed. Further heating causes the metal particles to aggregate so that the gap is filled therewith, whereby the metal layer 34 with a high metal density is formed, as shown in FIG. 15. In this case, the catalyst adsorption layer 24 may be decomposed depending on the heating temperature, or may remain on the substrate 10.

The line width of the metal layer 34 may be about twice the thickness of the metal layer 32. Therefore, the line width of the metal layer 34 can be controlled by adjusting the thickness of the metal layer 32. The thickness of the metal layer 32 may be controlled by changing the immersion time of the substrate 10 in the electroless plating solution 36, for example. The height of the metal layer 34 may be increased by increasing the height of the sacrificial layer 22. The aspect ratio can be easily controlled by adjusting the height of the sacrificial layer 22 and the thickness of the metal layer 32.

The first pattern and the second pattern are described below. The second pattern may have a shape along the first pattern. Since the metal particles forming the metal layer 32 aggregate in the region of the sacrificial layer 22 formed in the first pattern, as described above, the second pattern is provided within the region of the first pattern when the thickness of the metal layer 32 is equal to or larger than a specific value, and the first pattern is provided within the region of the second pattern when the thickness of the metal layer 32 is less than the specific value. When the thickness of the metal layer 32 is equal to the specific value, the first pattern is the same as the second pattern. The first pattern and the second pattern have an overlapping region irrespective of the thickness of the metal layer 32. Therefore, a metal layer 34 with a desired pattern can be formed by forming the sacrificial layer 22 with the desired pattern.

An element substrate 100 can be formed by the above steps, as shown in FIG. 15. Since the method of manufacturing the element substrate 100 according to this embodiment allows the line width a of the second pattern to be controlled by adjusting the thickness of the metal layer 32, the metal layer 34 with a highly accurate pattern can be formed independent of the accuracy of the sacrificial layer 22. According to this embodiment, since the metal layer can be formed by only the wet process, the manufacturing apparatus can be simplified, whereby cost can be reduced.

### 2. ELEMENT SUBSTRATE

The element substrate 100 includes the substrate 10 and the metal layer 34 formed on the substrate 10.

The metal layer 34 has the second pattern. The second pattern may be a one-dimensional or two-dimensional periodic pattern. If the element substrate 100 has the second pattern on an optically-transparent substrate, the element substrate 100 can function as an optical element substrate such as a polarizer. The element substrate 100 may have a one-dimensional periodic pattern (striped pattern) in which linear metal layers with a specific width are repeatedly formed at specific intervals. When the width in the periodic direction is equal to or less than the wavelength of visible light and the substrate 10 is an optically-transparent substrate, the element substrate 100 can function as a polarizer.

The line width a of the metal layer 34 can be adjusted to 10 nm or more and 100 nm or less, and more preferably 10 nm or more and 80 nm or less using the above manufacturing method. The height c of the metal layer 34 may be 60 nm or more and 140 nm or less, for example. The degree of integration of an electronic device to which the element substrate 100 is applied can be increased by forming the metal layer 34 with such a minute pattern. Moreover, the size of the element can be reduced. The element substrate 100 can also function as an excellent polarizer.

Specifically, when adjusting the line width a of the metal layer 34 a to about 20 nm, the thickness of the metal layer 32 may be adjusted to about 10 nm. The line width a of the metal layer 34 is preferably smaller than the interval b. The interval b is preferably 70 nm or more and 140 nm or less. This enables the adjacent metal layers 34 to be reliably disconnected.

### 3. ELECTRONIC DEVICE

FIG. 16 shows an example of an electronic device to which the element substrate 100 manufactured using the method of manufacturing an element substrate according to this embodiment is applied. When the substrate 10 is an insulating substrate, the element substrate 100 can function as a wiring board. An electronic device 1000 includes the element substrate 100 as a wiring board, an integrated circuit chip 90, and another substrate 92.

A wiring pattern formed on the element substrate 100 may be used to electrically connect electronic parts. The element substrate 100 is manufactured using the above-described manufacturing method. In the example shown in FIG. 16, the integrated circuit chip 90 is electrically connected with the element substrate 100. One end of the element substrate 100 is electrically connected with the other substrate 92 (e.g. display panel). The electronic device 1000 may be a display device such as a liquid crystal display device, a plasma display device, or an electroluminescent (EL) display device.

The element substrate 100 as an optical element substrate may function as a polarizer for a liquid crystal display device, a projector device, and the like.

### 4. EXPERIMENTAL EXAMPLE

Experimental examples according to this embodiment are described below.

### 4.1. Experimental Example 1

An element substrate was formed using the method of manufacturing an element substrate according to this embodiment. In Experimental Example 1, a platinum layer was formed by immersing a glass substrate in a platinum electroless plating solution for about 15 minutes. The manufacturing steps are as follows.

(1) A photoresist film was formed on a glass substrate. The photoresist film was exposed and developed using a direct drawing method in the shape of straight lines with a width of about 70 nm at a pitch of about 140 nm to form a striped photoresist pattern having straight lines with a width of about 70 nm at intervals of about 70 nm.

(2) The glass substrate was cut into 1×1 cm squares, and immersed in a cationic surfactant solution (FPD conditioner manufactured by Technic Japan Incorporated). The glass substrate was then immersed in a palladium catalyst solution to form a catalyst layer.

(3) The glass substrate on which the catalyst layer was formed was immersed in a platinum electroless plating solution at 40° C. for about 15 minutes to form a platinum layer with a thickness of about 30 nm in the region in which the catalyst layer was formed. As the platinum electroless plating solution, a solution was used which was prepared by mixing a commercially-available platinum plating solution (manufactured by Daiken Chemical Co., Ltd.) and a reducing agent solution (manufactured by Daiken Chemical Co., Ltd.) and adjusting the pH of the resulting mixture to about 10.0 using sulfuric acid.

(4) The glass substrate was then washed with pure water at room temperature.

(5) A heat treatment was then performed by RTA. The heat treatment was performed in air. The heat treatment temperature was set at 500° C., 600° C., 700° C., or 800° C. The heat treatment time was set at 10 minutes or 30 minutes.

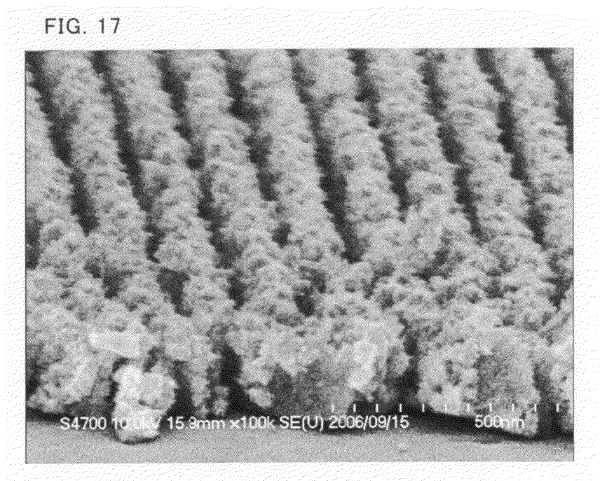

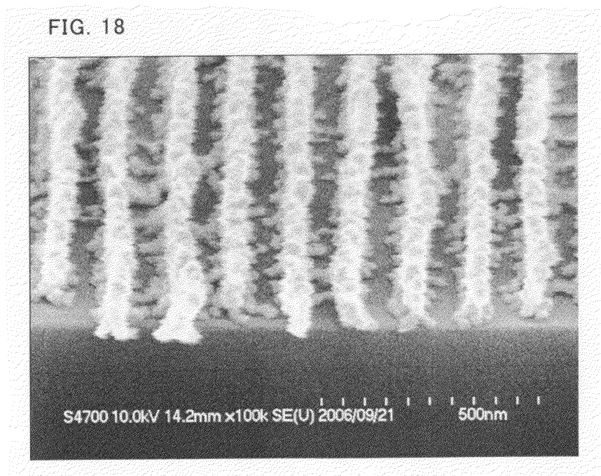

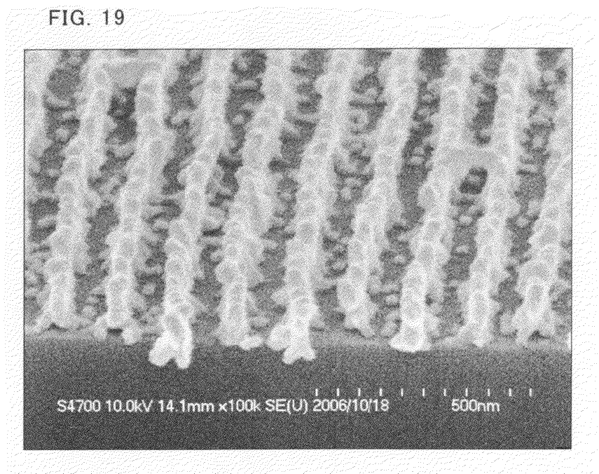

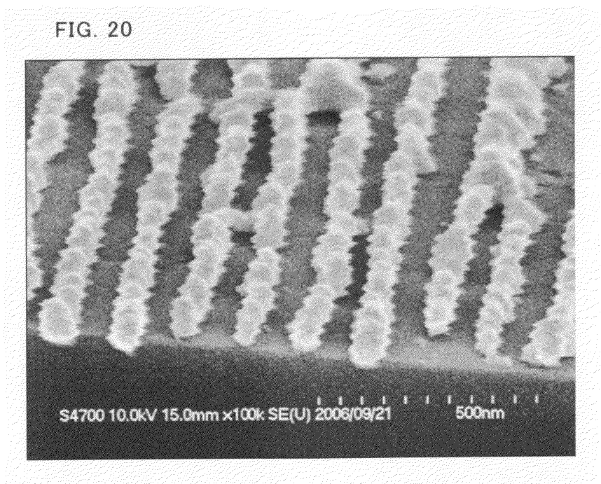

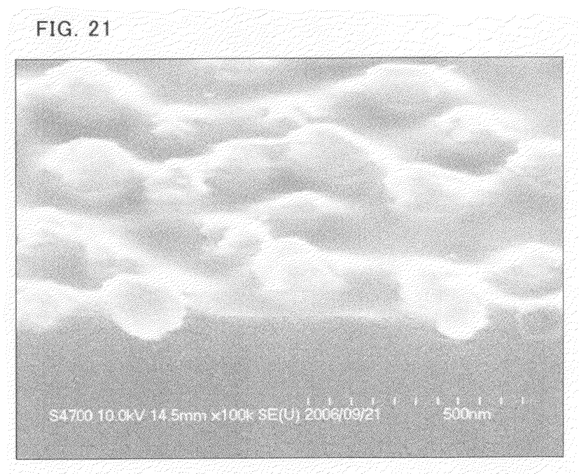

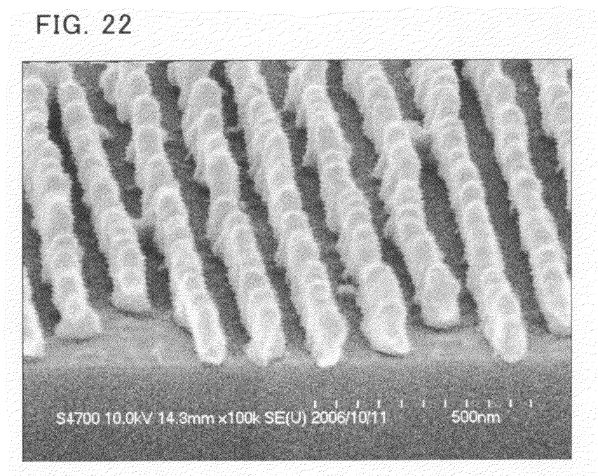

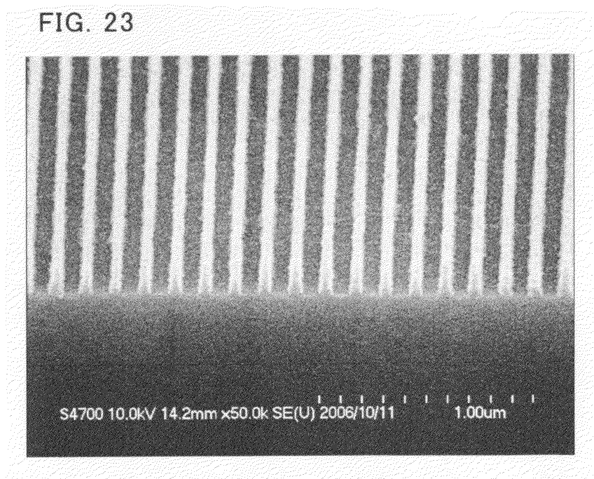

FIG. 17 shows an SEM image of the platinum layer before performing the step (5). FIGS. 18 to 21 show SEM images of the platinum layer after performing the step (5) while setting the heat treatment time at 10 minutes. FIG. 18 shows the SEM image when setting the heat treatment temperature at 500° C., FIG. 19 shows the SEM image when setting the heat treatment temperature at 600° C., FIG. 20 shows the SEM image when setting the heat treatment temperature at 700° C., and FIG. 21 shows the SEM image when setting the heat treatment temperature at 800° C. FIG. 22 shows an SEM image of the platinum layer when setting the heat treatment time at 30 minutes and setting the heat treatment temperature at 600° C. Table 1 shows pattern accuracy evaluation results based on these SEM images. In Table 1, a case where the pattern accuracy was excellent is indicated by “Excellent”, a case where the pattern accuracy was good is indicated by “Good”, and a case where the pattern accuracy was poor is indicated by “Poor”.

TABLE 1

| | Heat treatment | Heat treatment | |
|---|---|---|---|
| Drawing | time (min) | temperature (° C.) | Pattern accuracy |
| FIG. 18 | 10 | 500 | Good |
| FIG. 19 | 10 | 600 | Good |
| FIG. 20 | 10 | 700 | Good |
| FIG. 21 | 10 | 800 | Poor |
| FIG. 22 | 30 | 600 | Excellent |

As shown in FIG. 17, it was confirmed that the platinum layer was formed on the photoresist. Since the platinum layer with a thickness of about 30 nm was formed on the photoresist with a width of about 70 nm, the interval between the platinum layers was about 10 nm. The height of the platinum layer from the surface of the substrate was 150 to 200 nm. As shown in FIGS. 18 to 20 and 22, the platinum layer was in the shape of stripes having straight lines with a width (line width a) of about 70 to 80 nm at intervals (intervals b) of about 70 nm. The platinum layer had a height of about 100 nm and an aspect ratio of about 1.4.

As shown in FIGS. 18 to 20 and 22, the interval b between the platinum layers was increased to about 70 nm, and the photoresist was removed. The platinum particles aggregated in the region in which the photoresist was formed, and the adjacent lines were disconnected. The pattern accuracy was improved by setting the heat treatment time at 30 minutes as compared with the case of setting the heat treatment time at 10 minutes. Therefore, the heat treatment time is preferably set at 10 minutes or more, and more preferably 30 minutes or more. When setting the heat treatment temperature at 800° C., a platinum layer with an excellent pattern accuracy could not be obtained. Therefore, it is preferable to set the heat treatment temperature at less than 800° C. when forming the platinum layer.

### 4.2. Experimental Example 2

An element substrate was formed using the method of manufacturing an element substrate according to this embodiment. In Experimental Example 2, a platinum layer was formed by immersing a glass substrate in a platinum electroless plating solution for about 5 minutes. The manufacturing steps are as follows.

(1) A photoresist film was formed on a glass substrate. The photoresist film was exposed and developed using a direct drawing method in the shape of straight lines with a width of about 70 nm at a pitch of about 140 nm to form a striped photoresist pattern having straight lines with a width of about 70 nm at intervals of about 70 nm.

(2) The glass substrate was cut into 1×1 cm squares, and immersed in a cationic surfactant solution (FPD conditioner manufactured by Technic Japan Incorporated). The glass substrate was then immersed in a palladium catalyst solution to form a catalyst layer.

(3) The glass substrate on which the catalyst layer was formed was immersed in a platinum electroless plating solution at 40° C. for about 5 minutes to form a platinum layer with a thickness of about 10 nm in the region in which the catalyst layer was formed. As the platinum electroless plating solution, a solution was used which was prepared by mixing a commercially-available platinum plating solution (manufactured by Daiken Chemical Co., Ltd.) and a reducing agent solution (manufactured by Daiken Chemical Co., Ltd.) and adjusting the pH of the resulting mixture to about 10.0 using sulfuric acid.

(4) The glass substrate was then washed with pure water at room temperature.

(5) A heat treatment was then performed by RTA. The heat treatment was performed in air. The heat treatment temperature was set at 600° C., and the heat treatment time was set at 10 minutes.

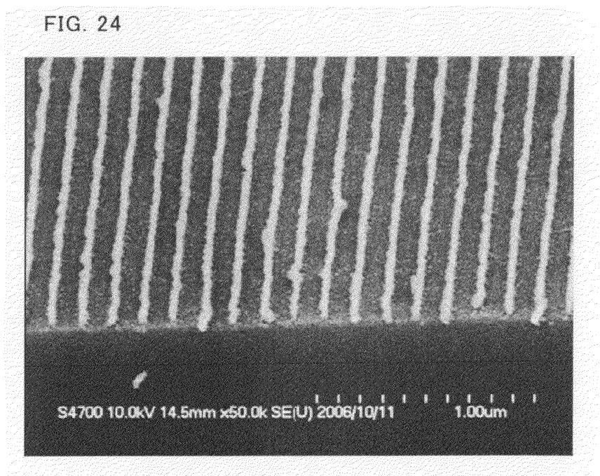

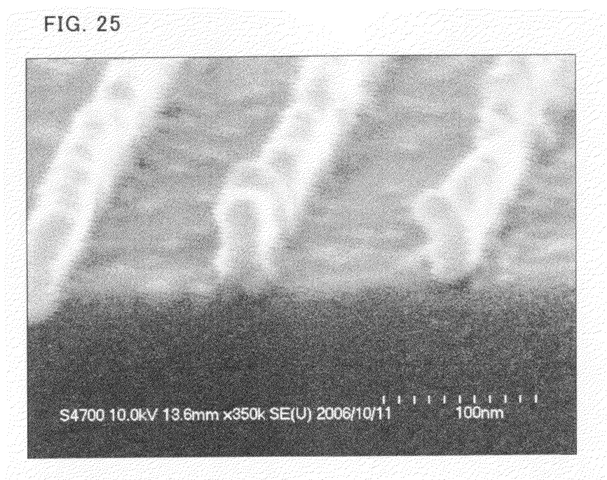

FIG. 23 shows an SEM image of the platinum layer before performing the step (5). FIGS. 24 and 25 show SEM images of the platinum layer after performing the step (5). FIG. 24 is a top view of the platinum layer, and FIG. 25 is an enlarged cross-sectional view of the platinum layer. As shown in FIG. 23, it was confirmed that the platinum layer was formed on the photoresist. As shown in FIG. 24, the platinum layer was in the shape of stripes having straight lines with a width of about 20 to 30 nm at intervals of about 110 to 120 nm. The platinum layer had a height of about 70 nm and an aspect ratio of about 2.9. As shown in FIGS. 24 and 25, the interval between the platinum layers was increased to about 110 nm, and the photoresist was removed. The platinum particles aggregated in the region in which the photoresist was formed, and the adjacent lines were completely disconnected.

The invention is not limited to the above-described embodiments, and various modifications can be made. The invention includes various other configurations substantially the same as the configurations described in the embodiments (in function, method and result, or in objective and result, for example). The invention also includes a configuration in which an unsubstantial portion in the described embodiments is replaced. The invention also includes a configuration having the same effects as the configurations described in the embodiments, or a configuration able to achieve the same objective. Further, the invention includes a configuration in which a publicly known technique is added to the configurations in the embodiments.

Although only some embodiments of this invention have been described in detail above, those skilled in the art will readily appreciate that many modifications are possible in the embodiments without materially departing from the novel teachings and advantages of this invention. Accordingly, all such modifications are intended to be included within the scope of the invention.

What is claimed is:

1. A method of manufacturing an element substrate comprising:
(a) forming a sacrificial layer with a first pattern on a substrate;
(b) forming a metal layer over a formation region and a non-formation region of the sacrificial layer; and
(c) removing the sacrificial layer by heating to give a second pattern to the metal layer.

2. The method of manufacturing an element substrate as defined in claim 1,
wherein a region of the first pattern is within a region of the second pattern.

3. The method of manufacturing an element substrate as defined in claim 1,
wherein a region of the second pattern is within a region of the first pattern.

4. The method of manufacturing an element substrate as defined in claim 1,
wherein, in the step (c), the metal layer is moved by heating to have the second pattern.

5. The method of manufacturing an element substrate as defined in claim 4,
wherein, in the step (c), the metal layer is moved to the formation region of the removed sacrificial layer by heating.

6. The method of manufacturing an element substrate as defined in claim 1,
wherein, in the step (b), the metal layer is formed by electroless plating.

7. The method of manufacturing an element substrate as defined in claim 6,
wherein the step (b) includes:
immersing the substrate in a catalyst adsorption solution containing a surfactant or a silane coupling agent to form a catalyst adsorption layer;
immersing the substrate having the catalyst adsorption layer in a catalyst solution to form a catalyst layer on the catalyst adsorption layer; and
immersing the substrate having the catalyst layer in an electroless plating solution to deposit the metal layer on the catalyst layer.

8. The method of manufacturing an element substrate as defined in claim 1,
wherein, in the step (c), the sacrificial layer is gasified and removed by heating.

9. The method of manufacturing an element substrate as defined in claim 8,
wherein the sacrificial layer includes a resin.

10. The method of manufacturing an element substrate as defined in claim 9,
wherein the step (a) includes:
applying a resin material in a fluid state to the substrate;
transferring the first pattern to the resin material by pressing a nanostamper having a depressed pattern of the first pattern against the substrate; and
curing the resin material having the transferred first pattern.

11. The method of manufacturing an element substrate as defined in claim 10, further comprising, between the steps (a) and (b),
removing an upper portion of the cured resin material and another part of the cured resin material in a region other than the first pattern by ashing.

12. The method of manufacturing an element substrate as defined in claim 9,
wherein the sacrificial layer includes a photoresist; and
wherein the sacrificial layer is formed by an interference exposure method in the step (a).

13. An element substrate comprising:
a substrate; and
a metal layer formed on the substrate by electroless plating and including a linear portion having a width of 10 nm to 100 nm.

14. The element substrate as defined in claim 13,
wherein the metal layer includes a plurality of the linear portions having the same width and being parallel to each other on the substrate.

15. The element substrate as defined in claim 13, wherein the linear portion has a width of 10 nm to 80 nm.

16. The element substrate as defined in claim 14,
wherein the linear portions have an interval of 70 nm to 140 nm in a direction of the width.

17. The element substrate as defined in claim 13, wherein the metal layer includes platinum.

18. The element substrate as defined in claim 14,
wherein the width of each of the linear portions is smaller than an interval between the linear portions in a direction of the width.

19. The element substrate as defined in claim 13, wherein the metal layer has an aspect ratio of 1 to 3.
